(19) United States
(12) Patent Application Publication
(10) Pub. No.: US 2016/0190364 A1
(43) Pub. Date: Jun. 30, 2016

(54) SEED LAYER FOR SOLAR CELL CONDUCTIVE CONTACT

(71) Applicants: Michael Cudzinovic, Sunnyvale, CA (US); Junbo Wu, San Jose, CA (US); Xi Zhu, Milpitas, CA (US)

(72) Inventors: Michael Cudzinovic, Sunnyvale, CA (US); Junbo Wu, San Jose, CA (US); Xi Zhu, Milpitas, CA (US)

(21) Appl. No.: 15/061,903

(22) Filed: Mar. 4, 2016

Related U.S. Application Data
(63) Continuation of application No. 13/706,728, filed on Dec. 6, 2012.

(51) Int. Cl. H01L 31/0224

(52) U.S. Cl. CPC H01L 31/022441

(57) ABSTRACT

Seed layers for solar cell conductive contacts and methods of forming seed layers for solar cell conductive contacts are described. For example, a solar cell includes a substrate. An emitter region is disposed above the substrate. A conductive contact is disposed on the emitter region and includes a conductive layer in contact with the emitter region. The conductive layer is composed of aluminum/silicon (Al/Si) particles having a composition of greater than approximately 15% Si with the remainder Al. In another example, a solar cell includes a substrate having a diffusion region at or near a surface of the substrate. A conductive contact is disposed above the diffusion region and includes a conductive layer in contact with the substrate. The conductive layer is composed of aluminum/silicon (Al/Si) particles having a composition of greater than approximately 15% Si with the remainder Al.

### CROSS-REFERENCE TO RELATED APPLICATIONS

This application is a continuation of U.S. patent application Ser. No. 13/706,728, filed on Dec. 6, 2012, the entire contents of which are hereby incorporated by reference herein.

### TECHNICAL FIELD

Embodiments of the present invention are in the field of renewable energy and, in particular, seed layers for solar cell conductive contacts and methods of forming seed layers for solar cell conductive contacts.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present invention allow for increased solar cell manufacture efficiency by providing novel processes for fabricating solar cell structures. Some embodiments of the present invention allow for increased solar cell efficiency by providing novel solar cell structures.

### BRIEF DESCRIPTION OF THE DRAWINGS

FIG. 1 is a plot of photoluminescence (PL) mid-point post-fire as a function of target silicon (Si) content within a paste additive, in accordance with an embodiment of the present invention.

FIG. 2A is a scanning electron microscopy (SEM) image of a silicon substrate following firing of a seed paste having 15% silicon relative to aluminum therein, in accordance with an embodiment of the present invention.

FIG. 2B is an SEM image of a silicon substrate following firing of a seed paste having 25% silicon relative to aluminum therein, in accordance with an embodiment of the present invention.

FIG. 3A illustrates a cross-sectional view of a portion of a solar cell having conductive contacts formed on emitter regions formed above a substrate, in accordance with an embodiment of the present invention.

FIG. 3B illustrates a cross-sectional view of a portion of a solar cell having conductive contacts formed on emitter regions formed in a substrate, in accordance with an embodiment of the present invention.

FIGS. 4A-4C illustrate cross-sectional views of various processing operations in a method of fabricating solar cells having conductive contacts, in accordance with an embodiment of the present invention.

### DETAILED DESCRIPTION

Seed layers for solar cell conductive contacts and methods of forming seed layers for solar cell conductive contacts are described herein. In the following description, numerous specific details are set forth, such as specific process flow operations, in order to provide a thorough understanding of embodiments of the present invention. It will be apparent to one skilled in the art that embodiments of the present invention may be practiced without these specific details. In other instances, well-known fabrication techniques, such as lithography and patterning techniques, are not described in detail in order to not unnecessarily obscure embodiments of the present invention. Furthermore, it is to be understood that the various embodiments shown in the figures are illustrative representations and are not necessarily drawn to scale.

Disclosed herein are solar cells having conductive contacts. In an embodiment, a solar cell includes a substrate. An emitter region is disposed above the substrate. A conductive contact is disposed on the emitter region and includes a conductive layer in contact with the emitter region. The conductive layer is composed of aluminum/silicon (Al/Si) particles having a composition of greater than approximately 15% Si with the remainder Al. In another embodiment, a solar cell includes a substrate having a diffusion region at or near a surface of the substrate. A conductive contact is disposed above the diffusion region and includes a conductive layer in contact with the substrate. The conductive layer is composed of aluminum/silicon (Al/Si) particles having a composition of greater than approximately 15% Si with the remainder Al. In yet another embodiment, a partially fabricated solar cell includes a substrate. An emitter region is disposed in or above the substrate. A conductive contact is disposed on a silicon region of the emitter region and includes a conductive layer in contact with the silicon region. The conductive layer is composed of aluminum/silicon (Al/Si) particles having a composition with a sufficient amount of Si such that the conductive layer does not consume a significant portion of the silicon region during an anneal of the conductive layer. The balance of the composition is Al.

One or more embodiments described herein are directed to controlling photoluminescence (PL) degradation in silicon based emitter regions by including silicon in printed conductive seed particles. More specifically, when forming conductive contacts from a first formed conductive printed seed layer, a paste composed of aluminum-silicon alloy particles can be printed. The paste is the fired or annealed to form an electrical contact to a device (and, e.g., to burn off solvent from the paste). Silicon from a device substrate or other silicon layer may rapidly dissolve into aluminum during a firing. When silicon is dissolved from the substrate it can create pits in the substrate. These pits can in turn cause high recombination at the surface of the device, causing a decrease in PL signal and reducing the device efficiency. In one ore more embodiments, the aluminum is deposited to also include sufficient silicon in the paste itself to hinder such dissolution of silicon from the substrate.

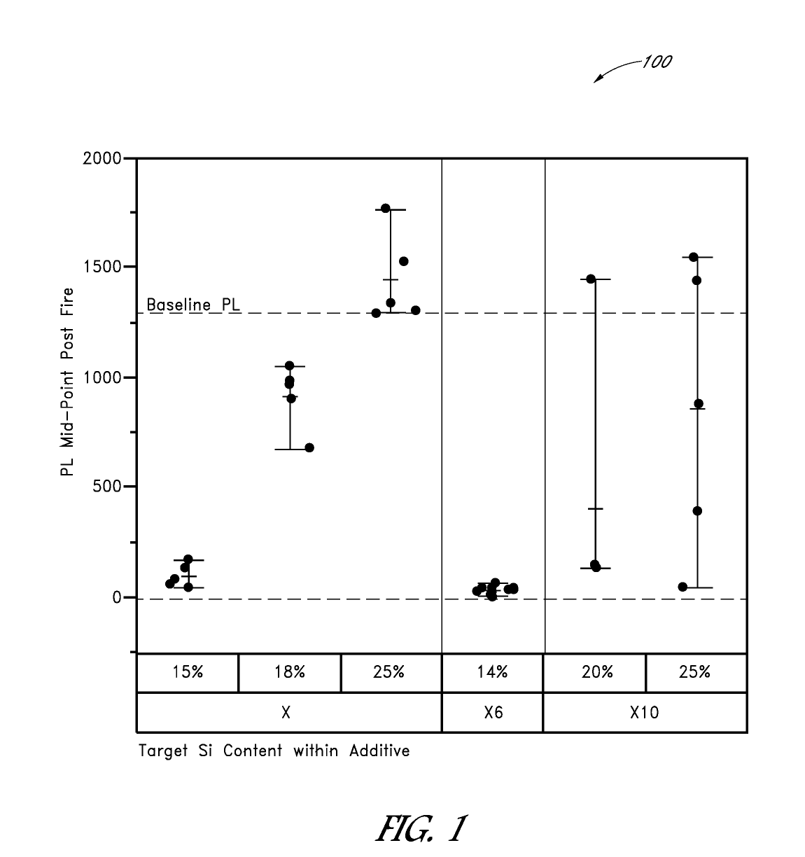

The formation of pits on silicon can be mitigated or eliminated by including some silicon in a deposited aluminum film, e.g., about 1% silicon can be effective. The added silicon dissolves in the aluminum at elevated temperatures such that little to no silicon is dissolved from the substrate. In an example, our own testing has shown that for a sputtered aluminum film fired at approximately 550 degrees Celsius, only approximately 2% silicon is required to prevent pitting. Furthermore, for firing temperatures above the aluminum-silicon eutectic of 577 degrees Celsius, the amount of silicon required is expected to follow the phase diagram. However, our testing of an aluminum film made from particles of aluminum approximately 5 microns in diameter and fired at approximately 580 degrees Celsius showed pitting when 12% silicon was included. Based on the phase diagram for Al/Si eutectics, the 12% included silicon should have been sufficient to reduce pitting and improve PL. In fact, we found that using less than 15% silicon in the particles was not sufficient to prevent PL degradation. Accordingly, for firing an aluminum paste at a temperature at or above the aluminum/silicon eutectic point, in an embodiment, more silicon is included in the paste than would otherwise be indicated by the phase diagram. However, in an embodiment, only so much silicon can be included before the paste is no longer an effective conducting paste. As an example, FIG. 1 is a plot 100 of photoluminescence (PL) mid-point post-fire as a function of target silicon (Si) content within a paste additive, in accordance with an embodiment of the present invention. As seen in plot 100, there is a relationship between PL degradation and silicon content.

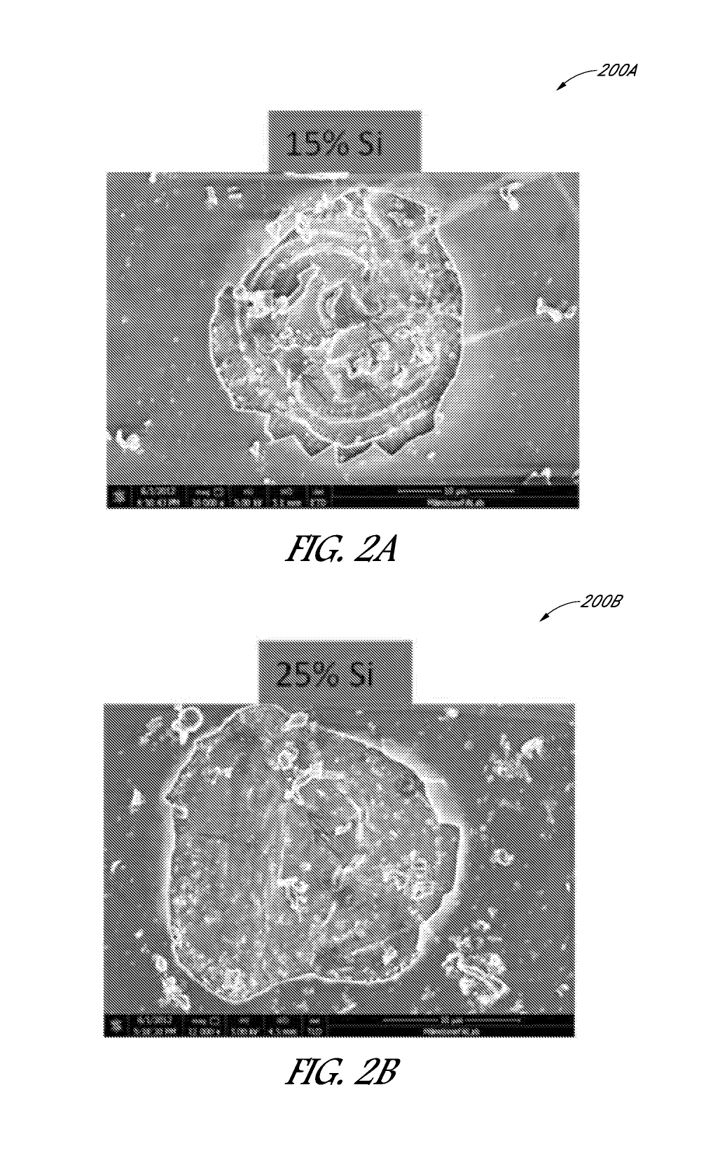

In an embodiment, greater than 15% silicon is included relative to aluminum in an aluminum-based conductive seed paste. In one such embodiment, as much as 25% silicon is used. The use of closer to 25% can decrease pitting in a silicon region having the paste deposited there on. For example, FIG. 2A is a scanning electron microscopy (SEM) image 200A of a silicon substrate following firing of a seed paste having 15% silicon relative to aluminum therein, while FIG. 2B is an SEM image 200B of a silicon substrate following firing of a seed paste having 25% silicon relative to aluminum therein, in accordance with an embodiment of the present invention. As can be seen in comparing images 200A and 200B, there was more pitting associated with 15% relative silicon versus 25% relative silicon.

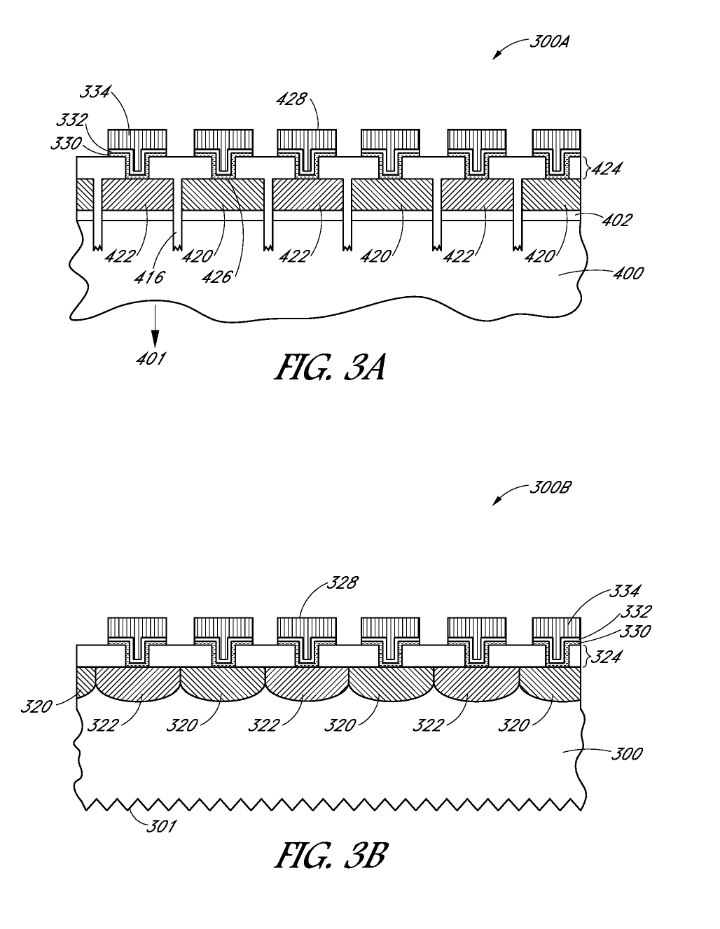

In a first aspect, a seed layer having Al/Si particles can be used to fabricate contacts, such as back-side contacts, for a solar cell having emitter regions formed above a substrate of the solar cell. For example, FIG. 3A illustrates a cross-sectional view of a portion of a solar cell having conductive contacts formed on emitter regions formed above a substrate, in accordance with an embodiment of the present invention.

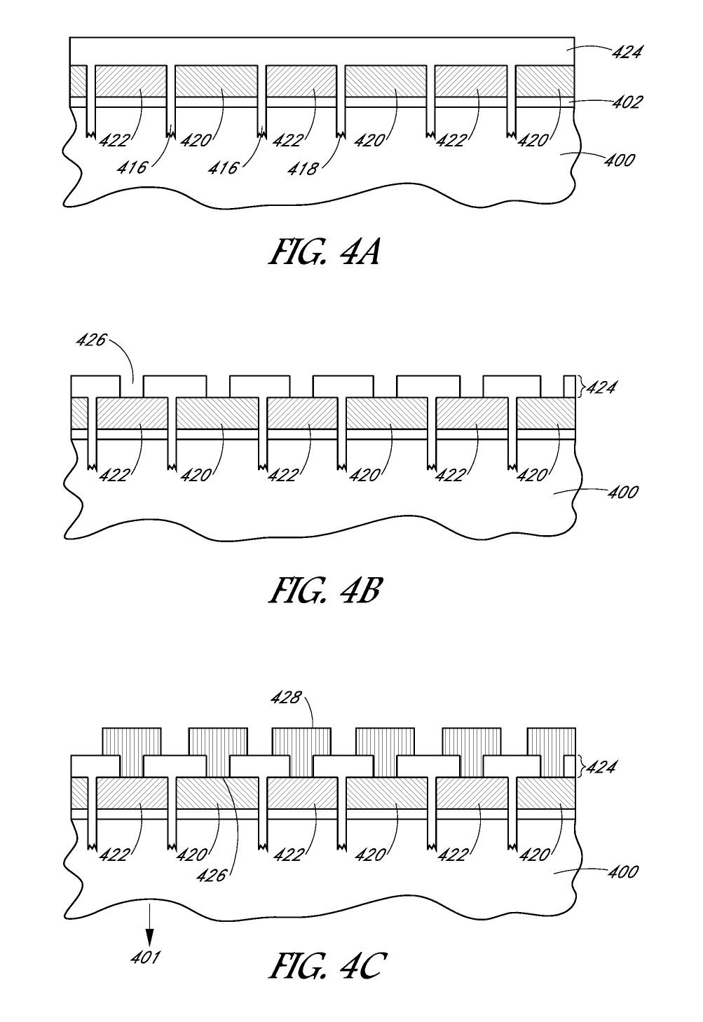

Referring to FIG. 3A, a portion of a solar cell 300A includes a patterned dielectric layer 424 disposed above a plurality of n-type doped polysilicon regions 420, a plurality of p-type doped polysilicon regions 422, and on portions of a substrate 400 exposed by trenches 416. Conductive contacts 428 are disposed in a plurality of contact openings disposed in the dielectric layer 424 and are coupled to the plurality of n-type doped polysilicon regions 420 and to the plurality of p-type doped polysilicon regions 422. The materials of, and methods of fabricating, the patterned dielectric layer, the plurality of n-type doped polysilicon regions 420, the plurality of p-type doped polysilicon regions 422, the substrate 400, and the trenches 416 may be as described below in association with FIGS. 4A-4C. Furthermore, the plurality of n-type doped polysilicon regions 420 and the plurality of p-type doped polysilicon regions 422 can, in one embodiment, provide emitter regions for the solar cell 300A. Thus, in an embodiment, the conductive contacts 428 are disposed on the emitter regions. In an embodiment, the conductive contacts 428 are back contacts for a back-contact solar cell and are situated on a surface of the solar cell opposing a light receiving surface (direction provided as 401 in FIG. 3A) of the solar cell 300A. Furthermore, in one embodiment, the emitter regions are formed on a thin or tunnel dielectric layer 402, described in greater detail in association with FIG. 4A.

In an embodiment, referring again to FIG. 3A, each of the conductive contacts 428 includes a conductive layer 330 in contact with the emitter regions of the solar cell 300A. In one such embodiment, the conductive layer 330 is composed of aluminum/silicon (Al/Si) particles, the particles having a composition of greater than approximately 15% Si with the remainder Al. In a specific such embodiment, the Al/Si particles have a composition of less than approximately 25% Si with the remainder Al. In an embodiment, the Al/Si particles are microcrystalline. In one such embodiment, the crystallinity of the Al/Si particles results from an anneal (such as, but not limited to, a laser firing) performed at a temperature approximately in the range of 550-580 degrees Celsius. However, in an alternative embodiment, the Al/Si particles are phase-segregated.

In an embodiment, the conductive layer 330 has a total composition including approximately 10-30% binders and frit, with the remainder the Al/Si particles. In one such embodiment, the binders are composed of zinc oxide (ZnO), tin oxide (SnO), or both, and the frit is composed of glass particles. It is to be understood that, when initially applied, a seed layer (e.g., an as-applied layer 330) further includes a solvent. However, the solvent is removed upon annealing the seed layer, leaving essentially the binders, frit and Al/Si particles in the final structure, as described above.

In an embodiment, the conductive layer 330 has a thickness greater than approximately 100 microns, and the conductive contact 428 fabricated there from is a back contact of the solar cell composed essentially of only the conductive layer 330. However, in another embodiment, the conductive layer 330 has a thickness of approximately 2-10 microns. In that embodiment, the conductive contact 428 is a back contact of the solar cell and is composed of the conductive layer 330, an electroless plated nickel (Ni) layer 332 disposed on the conductive layer 330, and an electroplated copper (Cu) layer 334 disposed on the Ni layer, as depicted in FIG. 3A.

In a second aspect, a seed layer having Al/Si particles can be used to fabricate contacts, such as back-side contacts, for a solar cell having emitter regions formed in a substrate of the solar cell. For example, FIG. 3B illustrates a cross-sectional view of a portion of a solar cell having conductive contacts formed on emitter regions formed in a substrate, in accordance with an embodiment of the present invention.

Referring to FIG. 3B, a portion of a solar cell 300B includes a patterned dielectric layer 324 disposed above a plurality of n-type doped diffusion regions 320, a plurality of p-type doped diffusion regions 322, and on portions of a substrate 300, such as a bulk crystalline silicon substrate. Conductive contacts 328 are disposed in a plurality of contact openings disposed in the dielectric layer 324 and are coupled to the plurality of n-type doped diffusion regions 320 and to the plurality of p-type doped diffusion regions 322. In an embodiment, the diffusion regions 320 and 322 are formed by doping regions of a silicon substrate with n-type dopants and p-type dopants, respectively. Furthermore, the plurality of n-type doped diffusion regions 320 and the plurality of p-type doped diffusion regions 322 can, in one embodiment, provide emitter regions for the solar cell 300B. Thus, in an embodiment, the conductive contacts 328 are disposed on the emitter regions. In an embodiment, the conductive contacts 328 are back contacts for a back-contact solar cell and are situated on a surface of the solar cell opposing a light receiving surface, such as opposing a texturized light receiving surface 301, as depicted in FIG. 3B.

In an embodiment, referring again to FIG. 3B, each of the conductive contacts 328 includes a conductive layer 330 in contact with the emitter regions of the solar cell 300B. In one such embodiment, the conductive layer 330 is composed of aluminum/silicon (Al/Si) particles, the particles having a composition of greater than approximately 15% Si with the remainder Al. In a specific such embodiment, the Al/Si particles have a composition of less than approximately 25% Si with the remainder Al. In an embodiment, the Al/Si particles are microcrystalline. In one such embodiment, the crystallinity of the Al/Si particles results from an anneal (such as, but not limited to, a laser firing) performed at a temperature approximately in the range of 550-580 degrees Celsius. However, in an alternative embodiment, the Al/Si particles are phase-segregated.

In an embodiment, the conductive layer 330 has a total composition including approximately 10-30% binders and frit, with the remainder the Al/Si particles. In one such embodiment, the binders are composed of zinc oxide (ZnO), tin oxide (SnO), or both, and the frit is composed of glass particles. It is to be understood that, when initially applied, a seed layer (e.g., an as-applied layer 330) further includes a solvent. However, the solvent is removed upon annealing the seed layer, leaving essentially the binders, frit and Al/Si particles in the final structure, as described above.

In an embodiment, the conductive layer 330 has a thickness greater than approximately 100 microns, and the conductive contact 328 fabricated there from is a back contact of the solar cell composed essentially of only the conductive layer 330. However, in another embodiment, the conductive layer 330 has a thickness of approximately 2-10 microns. In that embodiment, the conductive contact 328 is a back contact of the solar cell and is composed of the conductive layer 330, an electroless plated nickel (Ni) layer 332 disposed on the conductive layer 330, and an electroplated copper (Cu) layer 334 disposed on the Ni layer, as depicted in FIG. 3B.

Referring again to FIGS. 1 and 2B, and pertaining to FIGS. 3A and 3B, in an embodiment, a partially fabricated solar cell includes a substrate, an emitter region disposed in or above the substrate, and a conductive contact disposed on a silicon region of the emitter region (e.g., disposed on a polysilicon layer or on a silicon substrate). In one such embodiment, the conductive contact includes a conductive layer in contact with the silicon region. The conductive layer is composed of aluminum/silicon (Al/Si) particles having a composition with a sufficient amount of Si such that the conductive layer does not consume a significant portion of the silicon region during an anneal (such as a laser firing) of the conductive layer. In a specific embodiment, the remainder of the Al/Si composition is Al. In a particular embodiment, the Al/Si particles have a composition with greater than approximately 15% Si but less than approximately 25% Si, with the remainder Al.

The use of a conductive layer composed of aluminum/silicon (Al/Si) particles having a composition with a sufficient amount of Si such that the conductive layer does not consume a significant portion of a silicon region during an anneal can be used for structures having emitter regions formed from a silicon substrate or from a polysilicon layer formed above a substrate. For example, in a first embodiment, referring to FIG. 3A as a reference, a solar cell includes an emitter region composed of a polycrystalline silicon region disposed on a tunneling dielectric layer disposed on a substrate. The conductive layer is disposed a trench of an insulator layer disposed above the emitter region and is in contact with the polycrystalline silicon region. In one such embodiment, there is negligible to no pitting of the polycrystalline silicon region where the conductive layer is in contact with the polycrystalline silicon region. In another example, in a second embodiment, referring to FIG. 3B as a reference, a solar cell is fabricated from a bulk crystalline silicon substrate, and a conductive layer is disposed in a trench of an insulator layer disposed above the surface of the substrate. In one such embodiment, there is negligible to no pitting of the bulk crystalline silicon substrate where the conductive layer is in contact with the bulk crystalline silicon substrate.

Although certain materials are described specifically above, some materials may be readily substituted with others with other such embodiments remaining within the spirit and scope of embodiments of the present invention. For example, in an embodiment, a different material substrate, such as a group III-V material substrate, can be used instead of a silicon substrate. In another embodiment, silver (Ag) particles or the like can be used in a seed paste instead of, or in addition to, Al particles. In another embodiment, plated or like-deposited cobalt (Co) or tungsten (W) can be used instead of or in addition to the plated Ni described above.

Furthermore, the formed contacts need not be formed directly on a bulk substrate, as was described in FIG. 3B. For example, in one embodiment, conductive contacts such as those described above are formed on semiconducting regions formed above (e.g., on a back side of) as bulk substrate, as was described for FIG. 3A. As an example, FIGS. 4A-4C illustrate cross-sectional views of various processing operations in a method of fabricating solar cells having conductive contacts, in accordance with an embodiment of the present invention.

Referring to FIG. 4A, a method of forming contacts for a back-contact solar cell includes forming a thin dielectric layer 402 on a substrate 400.

In an embodiment, the thin dielectric layer 402 is composed of silicon dioxide and has a thickness approximately in the range of 5-50 Angstroms. In one embodiment, the thin dielectric layer 402 performs as a tunneling oxide layer. In an embodiment, substrate 400 is a bulk single-crystal substrate, such as an n-type doped single crystalline silicon substrate. However, in an alternative embodiment, substrate 400 includes a polycrystalline silicon layer disposed on a global solar cell substrate.

Referring again to FIG. 4A, trenches 416 are formed between n-type doped polysilicon regions 420 and p-type doped polysilicon regions 422. Portions of the trenches 416 can be texturized to have textured features 418, as is also depicted in FIG. 4A.

Referring again to FIG. 4A, a dielectric layer 424 is formed above the plurality of n-type doped polysilicon regions 420, the plurality of p-type doped polysilicon regions 422, and the portions of substrate 400 exposed by trenches 416. In one embodiment, a lower surface of the dielectric layer 424 is formed conformal with the plurality of n-type doped polysilicon regions 420, the plurality of p-type doped polysilicon regions 422, and the exposed portions of substrate 400, while an upper surface of dielectric layer 424 is substantially flat, as depicted in FIG. 4A. In a specific embodiment, the dielectric layer 424 is an anti-reflective coating (ARC) layer.

Referring to FIG. 4B, a plurality of contact openings 426 are formed in the dielectric layer 424. The plurality of contact openings 426 provide exposure to the plurality of n-type doped polysilicon regions 420 and to the plurality of p-type doped polysilicon regions 422. In one embodiment, the plurality of contact openings 426 is formed by laser ablation. In one embodiment, the contact openings 426 to the n-type doped polysilicon regions 420 have substantially the same height as the contact openings to the p-type doped polysilicon regions 422, as depicted in FIG. 4B.

Referring to FIG. 4C, the method of forming contacts for the back-contact solar cell further includes forming conductive contacts 428 in the plurality of contact openings 426 and coupled to the plurality of n-type doped polysilicon regions 420 and to the plurality of p-type doped polysilicon regions 422. In an embodiment, the conductive contacts 428 are composed of metal and are formed by a deposition (the deposition described in greater detail below), lithographic, and etch approach.

Thus, in an embodiment, conductive contacts 428 are formed on or above a surface of a bulk N-type silicon substrate 400 opposing a light receiving surface 401 of the bulk N-type silicon substrate 400. In a specific embodiment, the conductive contacts are formed on regions (422/420) above the surface of the substrate 400, as depicted in FIG. 4C. The forming can include forming a conductive layer composed of aluminum/silicon (Al/Si) particles having a composition with a sufficient amount of Si such that the conductive layer does not consume a significant portion of the silicon region during an anneal of the conductive layer. In a specific embodiment, the remainder of the Al/Si composition is Al. In a particular embodiment, the Al/Si particles have a composition with greater than approximately 15% Si but less than approximately 25% Si, with the remainder Al. Forming the conductive contacts can further include forming an electroless plated nickel (Ni) layer on the conductive layer. Additionally, a copper (Cu) layer can be formed by electroplating on the Ni layer.

In an embodiment, forming the conductive layer includes printing a paste on a bulk N-type silicon substrate or on a polysilicon layer formed above such as substrate. The paste can be composed of a solvent and the aluminum/silicon (Al/Si) alloy particles. The printing includes using a technique such as, but not limited to, screen printing or ink-jet printing. Additionally, one or more embodiments described herein are directed to approaches to, and structures resulting from, reducing the contact resistance of printed Al seed formed on a silicon substrate by incorporating the electroless-plated Ni therein. More specifically, one or more embodiments are directed to contact formation starting with an Al paste seed layer. Annealing is performed after seed printing to form contact between Al from the past and an underlying silicon substrate. Then Ni is deposited by electroless plating on top of Al paste. Since the paste has a porous structure, the Ni forms not only above, but also on the outside of the Al particles, and fills up at least a portion of the empty space. The Ni may be graded in that more Ni may form on upper portions of the Al (away from the Si). Nonetheless, the Ni on the outside of the Al particles can be utilized to reduce the contact resistance of a contact ultimately formed there from. In particular, if the thickness of the Al paste is generally reduced, more Ni can accumulate at the Al to silicon interface. When annealing is performed after Ni electroless plating, instead of after seed printing, a NiSi contact can form at the Ni—Si interface. Furthermore, an Al—Si contact can form at the Al—Si interface by having the Ni present in voids or pores of the Al particles. Compared to conventional approaches, the contacts formed can have a greater surface area of actual metal to silicon contact within a given region of the contact structure formation. As a result, the contact resistance can be lowered relative to conventional contacts.

Thus, seed layers for solar cell conductive contacts and methods of forming seed layers for solar cell conductive contacts have been disclosed. In accordance with an embodiment of the present invention, a solar cell includes a substrate. An emitter region is disposed above the substrate. A conductive contact is disposed on the emitter region and includes a conductive layer in contact with the emitter region. The conductive layer is composed of aluminum/silicon (Al/Si) particles having a composition of greater than approximately 15% Si with the remainder Al. In one embodiment, the Al/Si particles have a composition of less than approximately 25% Si with the remainder Al. In accordance with another embodiment of the present invention, a solar cell includes a substrate having a diffusion region at or near a surface of the substrate. A conductive contact is disposed above the diffusion region and includes a conductive layer in contact with the substrate. The conductive layer is composed of aluminum/silicon (Al/Si) particles having a composition of greater than approximately 15% Si with the remainder Al. In one embodiment, the Al/Si particles have a composition of less than approximately 25% Si with the remainder Al.

What is claimed is:

1. A method of fabricating a solar cell, the method comprising:
forming an emitter region above a substrate; and
forming a conductive contact on the emitter region, the conductive contact comprising a conductive layer formed in contact with the emitter region, the conductive layer comprising aluminum/silicon (Al/Si) particles having a composition consisting essentially of greater than approximately 15% Si with the remainder Al.

2. The method of claim 1, wherein the Al/Si particles have a composition consisting essentially of less than approximately 25% Si with the remainder Al.

3. The method of claim 1, wherein the Al/Si particles are microcrystalline.

4. The method of claim 1, wherein the conductive layer has a composition consisting essentially of approximately 10-30% binders and frit with the remainder the Al/Si particles.

5. The method of claim 4, wherein the binders comprise zinc oxide (ZnO), tin oxide (SnO), or both, and the frit comprises glass particles.

6. The method of claim 1, wherein the conductive layer has a thickness greater than approximately 100 microns, and wherein the conductive contact is a back contact of the solar cell consisting essentially of the conductive layer.

7. The method of claim 1, wherein the conductive layer has a thickness of approximately 2-10 microns, and wherein the conductive contact is a back contact of the solar cell comprising the conductive layer, an electroless plated nickel (Ni) layer formed on the conductive layer, and an electroplated copper (Cu) layer formed on the Ni layer.

8. The method of claim 3, wherein the crystallinity of the Al/Si particles results from annealing at a temperature approximately in the range of 550-580 degrees Celsius.

9. The method of claim 1, wherein the emitter region comprises a polycrystalline silicon region formed on a tunneling dielectric layer formed on the substrate, and the conductive layer is formed a trench of an insulator layer formed above the emitter region and is in contact with the polycrystalline silicon region, and wherein there is negligible to no pitting of the polycrystalline silicon region where the conductive layer is formed in contact with the polycrystalline silicon region.

10. A method of fabricating a solar cell, the method comprising:
forming a diffusion region at or near a surface of a substrate; and
forming a conductive contact above the diffusion region and comprising a conductive layer in contact with the substrate, the conductive layer comprising aluminum/silicon (Al/Si) particles having a composition consisting essentially of greater than approximately 15% Si with the remainder Al.

11. The method of claim 10, wherein the Al/Si particles have a composition consisting essentially of less than approximately 25% Si with the remainder Al.

12. The method of claim 10, wherein the Al/Si particles are microcrystalline.

13. The method of claim 10, wherein the conductive layer has a composition consisting essentially of approximately 10-30% binders and frit with the remainder the Al/Si particles.

14. The method of claim 13, wherein the binders comprise zinc oxide (ZnO), tin oxide (SnO), or both, and the frit comprises glass particles.

15. The method of claim 10, wherein the conductive layer has a thickness greater than approximately 100 microns, and wherein the conductive contact is a back contact of the solar cell consisting essentially of the conductive layer.

16. The method of claim 10, wherein the conductive layer has a thickness of approximately 2-10 microns, and wherein the conductive contact is a back contact of the solar cell comprising the conductive layer, an electroless plated nickel (Ni) layer formed on the conductive layer, and an electroplated copper (Cu) layer formed on the Ni layer.

17. The method of claim 12, wherein the crystallinity of the Al/Si particles results from annealing at a temperature approximately in the range of 550-580 degrees Celsius.

18. The method of claim 10, wherein the substrate is a bulk crystalline silicon substrate, and the conductive layer is formed in a trench of an insulator layer formed above the surface of the substrate, and wherein there is negligible to no pitting of the bulk crystalline silicon substrate where the conductive layer is formed in contact with the bulk crystalline silicon substrate.

19. A method of fabricating a solar cell, the method comprising:
forming an emitter region in or above a substrate; and
forming a conductive contact on a silicon region of the emitter region and comprising a conductive layer in contact with the silicon region, the forming comprising annealing the conductive layer, wherein the conductive layer comprises aluminum/silicon (Al/Si) particles having a composition consisting of a sufficient amount of Si such that the conductive layer does not consume a significant portion of the silicon region during the annealing of the conductive layer, with the remainder Al.

20. The method of claim 19, wherein the Al/Si particles have a composition consisting essentially of greater than approximately 15% Si but less than approximately 25% Si, with the remainder Al.
